(19) United States
(12) Patent Application Publication
(10) Pub. No.: US 2024/0222584 A1
(43) Pub. Date: Jul. 4, 2024

(54) DISPLAY APPARATUS AND METHOD FOR MANUFACTURING THE SAME

(71) Applicant: LG Display Co., Ltd., Seoul (KR)

(72) Inventors: Yuseop SHIN, Bucheon-si (KR); Dongseok LEE, Bucheon-si (KR); Jusang RHIM, Seoul (KR); Sunghwan YOON, Seoul (KR); Minjae KANG, Seoul (KR); Rokhee LEE, Seoul (KR); Yongseok KWAK, Paju-si (KR)

(73) Assignee: LG Display Co., Ltd., Seoul (KR)

(21) Appl. No.: 18/395,550

(22) Filed: Dec. 23, 2023

(30) Foreign Application Priority Data
Dec. 30, 2022 (KR) 10-2022-0190885

(51) Int. Cl. H01L 33/62; H01L 25/16; H01L 33/50

(52) U.S. Cl. CPC H01L 33/62; H01L 25/167; H01L 33/505

(57) ABSTRACT

A display apparatus includes a light emitting element disposed on a substrate: a planarization layer covering the light emitting element and comprising a plurality of holes disposed on both sides with the light emitting element interposed therebetween; a plurality of wire electrodes disposed on an exposed surfaces of the plurality of holes and electrically connected with the light emitting element; a plurality of assembly electrodes disposed on the planarization layer; a bank disposed on the plurality of assembly electrodes and comprising an assembly groove; and a color conversion layer disposed inside the assembly groove.

### CROSS-REFERENCE TO RELATED APPLICATION

This application claims the priority of Korean Patent Application No. 10-2022-0190885 filed on Dec. 30, 2022, which is hereby incorporated by reference in its entirety.

### BACKGROUND

### Field of the Disclosure

The present disclosure relates to a display apparatus, more particularly, a display apparatus including color conversion layer disposed by self-assembly, and a method for manufacturing the same.

### Description of the Background

Display apparatuses are applied to various electronic appliances such as TVs, mobile phones, laptops and tablets. To this end, research to develop thinning, lightening and low power consumption of display apparatuses is being continued.

Among display apparatuses, a light emitting display apparatus has a light emitting element or light source embedded therein and displays information through light generated from the embedded light emitting element or light source. A display apparatus including a self-light emitting (i.e., luminescent) element may have an advantage of realizing a thinner display apparatus than a display apparatus having the light source, and another advantage of realizing a flexible display apparatus that may be folded, bent or rolled.

The display apparatus having the embedded luminescent element may include an OLED (Organic Light Emitting Display) having an organic material disposed as a light emitting layer or Micro LED (Micro Light Emitting Diode) having an inorganic material disposed as a light emitting layer. Here, the organic light emitting display does not requires a separate light source but has a disadvantage of defective pixels that might easily occur due to external environment of organic materials vulnerable to moisture and oxygen. As it uses an inorganic material resistant to moisture and oxygen as a light emitting layer, the micro LED display apparatus is not affected by the external environment and has high reliability and a long lifespan, compared to the organic light emitting display apparatus.

### SUMMARY

Accordingly, the present disclosure is directed to a display apparatus and a method for manufacturing the same that substantially obviate one or more of problems due to limitations and disadvantages described above.

More specifically, the present disclosure is to provide a display apparatus having a high-density color conversion layer.

The present disclosure is also to provide a display apparatus that can prevent a decrease in color conversion efficiency by preventing a decrease in efficiency of a phosphor introduced into a color conversion layer.

The present disclosure is not limited to the above-described and other advantages of the present disclosure will be understood by the following description and will be more definitely understood through the aspects of the present disclosure. It is also to be easily understood that the advantages of the present disclosure may be realized and attained by means and a combination thereof described in the appended claims.

To achieve these and other advantages and in accordance with the present disclosure, as embodied and broadly described, a display apparatus includes a light emitting element disposed on a substrate: a planarization layer covering the light emitting element and comprising a plurality of holes disposed on both sides with the light emitting element interposed therebetween; a plurality of wire electrodes disposed on an exposed surfaces of the plurality of holes and electrically connected with the light emitting element; a plurality of assembly electrodes disposed on the planarization layer; a bank disposed on the plurality of assembly electrodes and comprising an assembly groove; and a color conversion layer disposed inside the assembly groove.

In another aspect of the present disclosure, a method for manufacturing a display includes preparing a substrate; wherein the substrate comprises; a light emitting element: a planarization layer covering the light emitting element and comprising a plurality of holes disposed on both sides with the light emitting element interposed therebetween; a plurality of wire electrodes disposed on an exposed surfaces of the plurality of holes and electrically connected with the light emitting element; a plurality of assembly electrodes disposed on the planarization layer; a bank disposed on the plurality of assembly electrodes and comprising an assembly groove; and a color conversion material adhesive layer disposed inside the assembly groove; disposing the substrate in a fluid in which core shell phosphor particles are scattered; moving the core shell phosphor particles toward the assembly groove; generating an electric field around the plurality of assembly electrodes; and forming a color conversion layer by moving the core-shell phosphor particles dielectrically polarized by the electric field toward the assembly electrode and fixing the dielectrically polarized core shell phosphor particles on the color conversion material adhesive layer.

According to an aspect of the present disclosure, a high density phosphor color conversion layer may be formed by using dielectrophoresis.

In addition, a phosphor layer may be easily fixed to a position at which the color conversion layer has to be disposed by applying a material having adhesiveness to a position at which the color conversion layer will be formed, thereby realizing process optimization.

According to the aspects of the present disclosure, the high density phosphor color conversion layer may be formed by using dielectrophoresis. Accordingly, color gamut may be improved through the high-density phosphor color conversion layer and contact time may be reduced in comparison with the conventional deposition of the phosphor by using the inkjet method, thereby improving productivity.

In addition, color gamut may be improved and color conversion efficiency may be increased by forming the high-density phosphor color conversion layer, thereby improving conductivity.

In addition, the present disclosure may exclude a process of reducing the size of a phosphor to a sub-micron particle size so that efficiency of a color conversion material may be improved, thereby realizing process optimization.

In addition to the above-described effects, specific effects of the present disclosure will be described together with the following detailed description for implementing the present disclosure.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic plan view of a display apparatus according to an aspect of the present disclosure;

FIG. 2 is a cross-sectional view of one sub-pixel among a plurality of sub-pixels in a display apparatus according to an aspect of the present disclosure; and

FIGS. 3 to 8 are schematic views showing a method for manufacturing the display apparatus according to the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various aspects are illustrated and described further below. It will be understood that the description herein is not intended to limit the claims to the specific aspects described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating aspects of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated.

When a certain aspect may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “aspects,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating aspects.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each aspect of the present disclosure will be described with reference to the accompanying drawings.

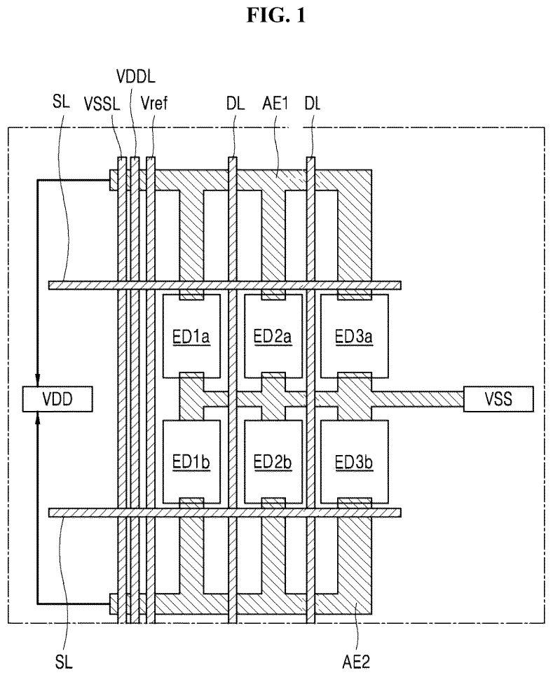

FIG. 1 is a schematic plan view of a display apparatus according to an aspect of the present disclosure.

Referring to FIG. 1, a display apparatus according to an aspect may include a plurality of sub-pixels. Each of the sub-pixels may include at least one light emitting element ED1a, ED2a and ED3a. For example, the light emitting elements ED1a, ED2a and ED3a may include a first light emitting element ED1a, a second light emitting element ED2a and a third light emitting element ED3a for emitting red R, green G and Blue lights, respectively.

In addition, each of the sub-pixels may further include a redundancy light emitting element ED1b, ED2b or ED3b for a repair process. For example, the redundancy light emitting element ED1b, ED2b or ED3b may include a first redundancy light emitting element ED1b, a second redundancy light emitting element ED2b or a third redundancy light emitting element ED3b, which are corresponding to the first light emitting element ED1a, the second light emitting element ED2a or the third light emitting element ED3a, respectively.

The display apparatus may include a first drive power line VDDL and a second drive power line VSSL which transmit a first drive power VDD and a second drive power VSS, respectively, for driving the plurality of light emitting elements, and a reference voltage line Vref which transmits a reference voltage. In addition, the display apparatus may include a data line DL transmitting a data signal and a scan line SL transmitting a scan signal.

The plurality of light emitting elements according to an aspect may be connected with a first assembly electrode AE1 and a second assembly electrode AE2, which are alignment electrodes for self-assembly of phosphors.

The light emitting element according to the aspect may be a micro LED. For example, the micro LED according to the aspect may emit a blue light. The blue light may emit red or green light while passing through a color conversion layer CCL disposed above the light emitting element.

The color conversion layer CCL may include a phosphor. The density of the color conversion layer is an important variable to increase color conversion efficiency for converting a blue light passing through the color conversion layer into a light of a desired color. The density of the color conversion layer may be understood as the thickness of the color conversion layer.

The lower the density of the color conversion layer, the lower the probability of contact of the blue light passing through the color conversion layer with the phosphor, so that the color conversion efficiency may be lower. In other words, the higher the density of the color conversion layer, the higher the probability that the blue light passing through the color conversion layer contacts the phosphor. As the probability of contact with the phosphor increases, the efficiency of color conversion into the desired color light may increase, the frontal luminance of the light passing through the color conversion layer may increase, and the color gamut may be improved.

However, in case the phosphor is applied by an inkjet method, process efficiency might be deteriorated and it could be difficult to control the density of the color conversion layer. For example, to apply the phosphor according to the inkjet method, phosphor particles having a submicron size are required. However, efficiency deterioration might occur during the process of reducing the size of the phosphor to the submicron size. In addition, the phosphor applied by the inkjet method increases the density of the color conversion layer through volatilization. During the volatilization process, it becomes difficult to control the density of the color conversion layer and then the color conversion efficiency might deteriorate.

To solve this problem, the aspect of the present disclosure may realize the high-density color conversion layer, thereby improving color conversion efficiency of the light emitted from the micro LED, which will be described next, referring to the accompanying drawings.

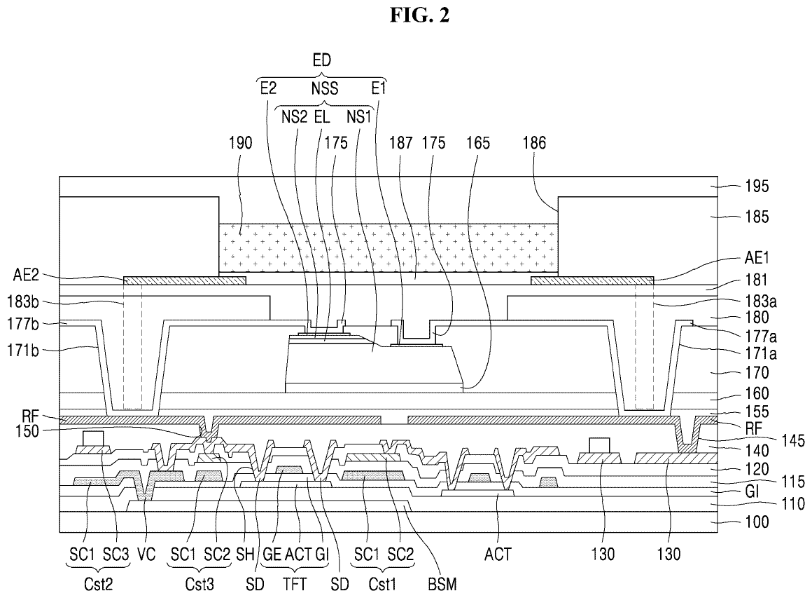

FIG. 2 is a cross-sectional view of one sub-pixel among a plurality of sub-pixels in a display apparatus according to an aspect of the present disclosure.

Referring to FIG. 2, a thin film transistor TFT is disposed on a substrate 100. The thin film transistor TFT may include a semiconductor layer ACT, a gate electrode GE, and a gate insulation layer GI disposed between the semiconductor layer ACT and the gate electrode GE. Accordingly, reliability of the thin film transistor TFT may be improved by disposing a light blocking layer BSM on the substrate 100. The light blocking layer BSM may include an opaque conductive material. A buffer layer 110 may be disposed between the substrate 100 and the light blocking layer BSM.

A plurality of first capacitor electrodes SC1 may be disposed on the gate insulation layer GI on the same plane with the gate electrode GE. A first interlayer insulation film 115 may be disposed on the gate electrode GE. A plurality of second capacitor electrodes SC2 may be disposed on the first interlayer insulation film 115. The plurality of second capacitor electrodes SC2 may be disposed by overlapping each of the first capacitor electrodes SC1, using the first interlayer insulation film 115 as a dielectric, thereby forming a plurality of storage capacitors Cst1 and Cst3.

A second interlayer insulation film 120 may be disposed on the first interlayer insulation film 115. A plurality of signal wires 130 may be disposed on the second interlayer insulation film 120. For example, the signal wires 130 may be data lines, first driving power lines and a second driving power lines. A third capacitor electrode SC3 may be disposed on the second interlayer insulation film 120 and overlap with the first capacitor electrode SC2 with the first interlayer insulation film 115 and the second interlayer insulation film 120 interposed therebetween, thereby constituting a different storage capacitor Cst2.

A source/drain electrode SD for filling in a source/drain contact hole SH penetrating the first interlayer insulation film 115, the second interlayer insulation film 120 and the gate insulation layer G1 may be disposed. Source/drain electrodes SD may be disposed on both sides with the gate electrode GE interposed therebetween, respectively. One of the source/drain electrodes SD may be in contact with some area of a surface of the light blocking layer BSM exposed by via-contact VC penetrating the gate insulation layer GI and the buffer layer 110.

A first planarization layer 140 may be disposed to cover the plurality of signal wires 130 and source/drain electrodes SD. A contact hole 145 and 150 may formed to some area of the surface of the signal wires 130 and some area of the surface of the source/drain electrode SD through the first planarization layer 140.

A first contact hole 145 may expose some area of the surface of one signal wire 130 among the plurality of signal wires 130. The second contact hole 150 may expose some area of the surface of the source/drain electrode SD. A reflective electrode RF may be disposed on the exposed surfaces of the first and second contact holes 145 and 150 and the first planarization layer 140. The reflective electrode RF may reflect light, which is emitted toward the substrate 100 among the lights emitted from the light emitting element, to a light emitting area. The reflective electrode RF may include a metal material having a high reflectivity. For example, the reflective electrode RF may include aluminum Al or silver Ag. The reflective electrode RF may be covered by a protective layer 155. An adhesion protective layer 160 having adhesiveness may be disposed on the protective layer 155, and an adhesive layer 165 may be disposed on the adhesion protective layer 160 at a position corresponding to the position of the light emitting element ED.

The light emitting element ED may be attached to the adhesive layer 165. The adhesive layer 165 may be a layer for adhering the light emitting element ED on reflective electrode RF. The adhesive layer 165 may insulate the reflective electrode RF made of a metal material from the light emitting element ED. The adhesive layer 165 may be made of a heat curing material or a light curing material, but the aspect of the present disclosure is not limited thereto. Meanwhile, FIG. 2 shows that the adhesive layer 165 is disposed in some areas overlapping the reflective electrode RF but the aspect is not limited thereto. For example, the adhesive layer 165 may be disposed on a front surface of the substrate 100.

The light emitting element ED may include a nitride semiconductor structure NSS, a first electrode E1 and a second electrode E2. The light emitting element ED may be a micro LED and emit a blue light. The nitride semiconductor structure NSS may include a first semiconductor layer NS1, an active layer EL, a second semiconductor layer NS2, a first electrode E1 disposed on the first semiconductor layer NS1, and a second electrode E2 disposed on the second semiconductor layer NS2. The active layer EL and the second semiconductor layer NS2 of the nitride semiconductor structure NSS are disposed on one side of a top surface of the first semiconductor layer NS1.

The first semiconductor layer NS1 may be a layer for supplying an electron to the active layer EL, and may include a nitride-based semiconductor having a first conductive impurity. For example, the first conductive impurity may include an N-type impurity. The active layer EL disposed on one side of the top surface of the first semiconductor layer NS1 may be a layer for emitting light, and may include a well layer and a multi quantum well structure having barrier layer having a higher band gap than the well layer.

The second semiconductor layer NS2 is a layer for injecting holes into the active layer EL. The second semiconductor layer NS2 may include a nitride-based semiconductor having a second conductive impurity. For example, the second conductive impurity may include a P-type impurity. The active layer EL may emit light from combination of the electrons supplied from the first semiconductor layer NS1 and the second semiconductor layer NS2 with the holes.

The light emitting element ED may be covered by a second planarization layer 170. The second planarization layer 170 may include a photoactive compound PAC, for example.

The second planarization layer 170 may include a first hole 171a and a second hole 171b disposed on both sides with the light emitting element ED interposed therebetween. The second planarization layer 170 may include an open portion 175 for exposing a predetermined surface area of each of the first and second electrodes E1 and E2 provided in the light emitting element ED. The first hole 171a and the second hole 171b may expose some surface area of the reflective electrode RF by penetrating the second planarization layer 170 and the adhesion protective layer 160. A first wire electrode 177a and a second wire electrode 177b may be provided on the exposed surface areas of the first hole 171a and the second hole 171b, respectively. The first wire electrode 177a and the second wire electrode 177b may extend to be linked to the first electrode E1 and the second electrode E2 exposed by the open portion 175.

The first electrode E1 of the light emitting element ED may be electrically connected with the signal wires 130 through the first wire electrode 177a linked to the reflective electrode RF. The second electrode E2 of the light emitting element ED may be electrically connected with the source/drain electrode SD through the second wire electrode 177b. The first electrode E1 and the second electrode E2 may be made of the same material, and may include a transparent metal oxide such as indium-tin-oxide (ITO) and indium-zinc-oxide (IZO).

The first hole 171a and the second hole 171b may be filled with a material constituting a buried pattern 180. A third planarization layer 181 may be disposed on the buried pattern 180.

Assembly electrodes AE1 and AE2 may be disposed on the third planarization layer 181. The assembly electrodes AE1 and AE2 may include a first assembly electrode AE1 and a second assembly electrode AE2, which are disposed on both sides with the light emitting element ED interposed therebetween, spaced apart from each other.

Through-electrodes 183a and 183b penetrating the third planarization layer 181 and the buried pattern 180 may be provided at a position corresponding to the buried pattern 180. One surface of each through-electrode 183a and 183b may be contacted to a rear surface of each assembly electrode AE1 and AE2, and the other surface thereof may be connected to the first wire electrode 177a and the second wire electrode 177b.

The assembly electrodes AE1 and AE2 may be electrically connected with the signal wires 130 through the first wire electrode 177a and the second wire electrode 177b. Through this, voltage for forming the color conversion layer may be transmitted to the assembly electrodes AE1 and AE2 connected with the through-electrodes 183a and 183b.

A bank 185 may be disposed on the first assembly electrode AE1 and the second assembly electrode AE2. The bank 185 may include an assembly groove 186. The assembly groove 186 may be provided at a position corresponding to an area where the light emitting element ED is disposed. The bank 185 may extend to the third planarization layer 181, while covering the assembly electrodes AE1 and AE2. The assembly groove 186 formed on the bank 185 may expose some surface areas of the assembly electrodes AE1 and AE2. An electric field may be generated by the voltage transmitted through the signal wires and the through-electrodes 183 and 183b, when the color conversion layer is formed based on a dielectrophoretic method by the exposed areas of the assembly electrodes AE1 and AE2.

A color conversion material adhesive layer 187 may be disposed to partially fill in the assembly groove 186, while covering the exposed surfaces of the first assembly electrode AE1 and the second assembly electrode AE2. The color conversion material adhesive layer 187 may server to fix the color conversion layer 190 inside the assembly groove 186.

The color conversion layer 190 may be disposed on the color conversion material adhesive layer 187 and configured to partially fill in the assembly groove 186. The color conversion layer 190 may have a uniform thickness at the center or edge of the assembly groove 186. In other words, the center or the edge of the assembly groove 186 may have the same thickness.

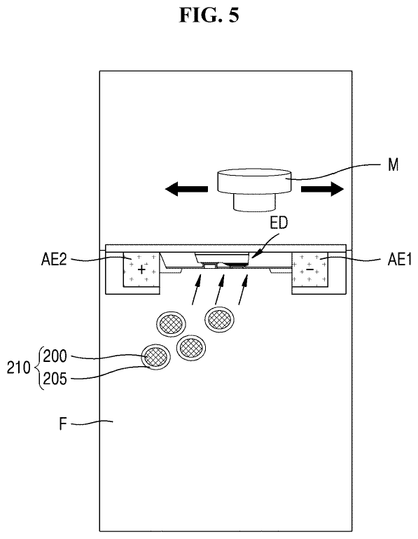

The assembly electrodes AE1 and AE2 may be protruded toward the inside of the assembly groove 186 from the edge of the bank 185 so that they may partially overlap the color conversion layer 190. Accordingly, the assembly electrodes AE1 and AE2 may be made of a transparent material. The color conversion layer 190 may include a plurality of phosphor core shell particles each having a core and a shell surrounding the outside of the core. The plurality of phosphor core shell particles will be described in detail later, referring to FIG. 5.

A cover layer 195 may be disposed on the bank 185 including the color conversion layer 190. The cover layer may include a functional optical film such as an anti-shattering film. The cover layer 195 may be attached on the color conversion layer 190 via an optically clear adhesive OCA, but the aspect is not limited thereto.

According to the aspect of the present disclosure, the color conversion layer 190 may have the uniform thickness at the center or edge of the assembly groove 186, so that the high density color conversion layer 190 may be provided. Accordingly, color conversion efficiency of the light passing through the color conversion layer 190 may be improved and front luminance may be improved as well.

Hereinafter, a method for manufacturing a display apparatus including the high-density color conversion layer 190 will be described.

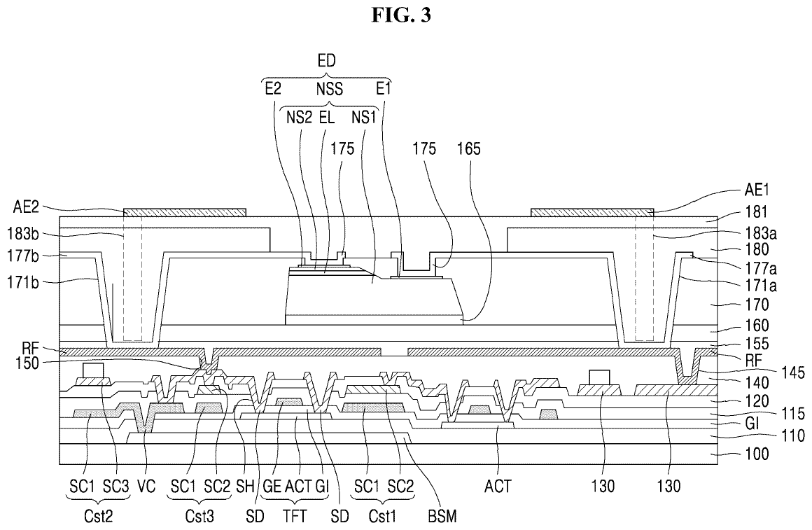

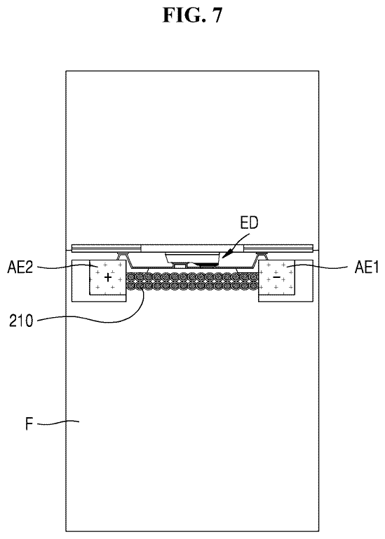

FIGS. 3 to 8 are schematic views showing a method for manufacturing the display apparatus according to the present disclosure. A light emitting element ED and a plurality of circuit elements for driving the light emitting element, which are shown in FIG. 3, may have the same configuration. Accordingly, the same configuration indicated as the same numeral references will be described briefly or omitted.

Referring to FIG. 3, assembly electrodes AE1 and AE2 may be disposed on the substrate 100 on which the light emitting element ED is disposed.

The light emitting element ED and various circuit elements for driving the light emitting element ED may be disposed on the substrate 100. For example, the various circuit elements may include a thin film transistor TFT, a plurality of capacitors Cst1, Cst2 and Cst3, and a plurality of signal wires 130. A first planarization layer 140 may be disposed on the thin film transistor TFT, the plurality of storage capacitors Cst1, Cst2 and Cst3, and the plurality of signal wires 130. The first planarization layer 140 may make flat a step formed by the various circuit elements disposed below.

The first planarization layer 140 may include a first contact hole 145 for exposing some surface area of one signal wire 130 among the plurality of signal wires 130 and a second contact hole 150 for exposing some surface area of a source/drain electrode SD. A reflective electrode RF may be disposed on surfaces of the first and second contact holes 145 and 150. The reflective electrode RF may include a metal material having a high reflectivity. The reflective electrode RF may be covered by a protective layer 155. An adhesion protective layer 160 having adhesiveness may be disposed on the protective layer 155, and an adhesive layer 165 may be disposed on the adhesion protective layer 160 at a position corresponding to the position of the light emitting element ED. The light emitting element ED may be attached on the adhesive layer 165. The adhesive layer 165 may disposed on a front surface of the substrate 100 under the light emitting element ED.

A second planarization layer 170 for surrounding the light emitting element ED may be disposed. The second planarization layer 170 may include a first hole 171a and a second hole 171b which are disposed on both sides with the light emitting element ED interposed therebetween. A first wire electrode 177a and a second wire electrode 177b may be provided on the exposed surface areas of the first hole 171a and the second hole 171b, respectively. The first electrode E1 of the light emitting element ED may be electrically connected with the signal wires 130 through the first wire electrode 177a. The second electrode E2 of the light emitting element ED may be electrically connected with the source/drain electrode SD through the second wire electrode 177b.

The first hole 171a and the second hole 171b may be filled with a material constituting a buried pattern 180. A third planarization layer 181 may be disposed on the buried pattern 180. Assembly electrodes AE1 and AE2 may be disposed on the third planarization layer 181.

The assembly electrodes AE1 and AE2 may be made of transparent electrodes including a transparent metal oxide such as indium-tin-oxide (ITO) or indium-zinc-oxide (IZO). The assembly electrodes AE1 and AE2 may include a transparent metal material that may form an electric field. Each of the assembly electrodes AE1 and AE2 may protrude from an edge of the bank 185 and overlaps a color conversion layer, which will be formed later.

The assembly electrodes AE1 and AE2 may include a first assembly electrode AE1 and a second assembly electrode AE2 which are spaced apart from each other with the light emitting element ED interposed therebetween.

Through-electrodes 183a and 183b may be formed on rear surfaces of the first assembly electrode AE1 and the second assembly electrode AE2 to be connected with the reflective electrode RF after penetrating the buried pattern 180. The through-electrodes 183a and 183b may allow voltage to be applied on the first assembly electrode AE1 and the second assembly electrode AE2 to perform dielectrophoresis.

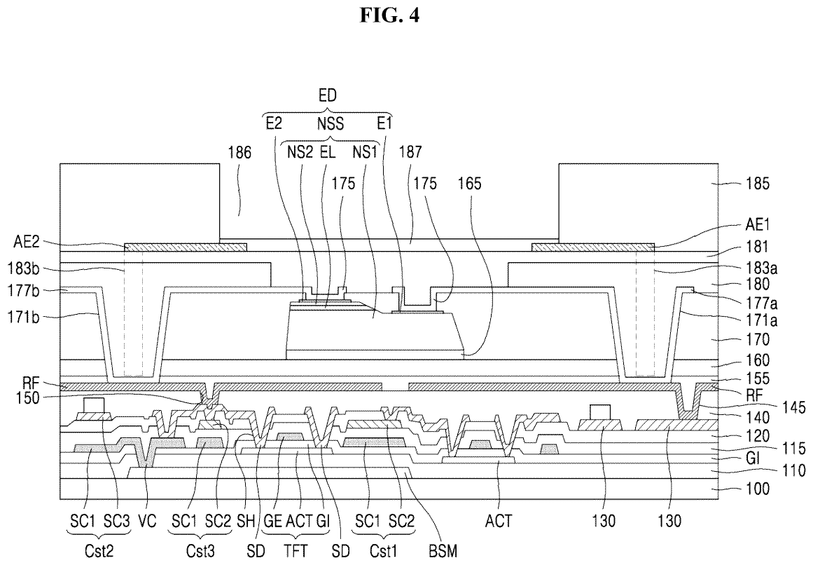

Referring to FIG. 4, a bank 185 may be formed on the first assembly electrode AE1 and the second assembly electrode AE2. The bank 185 may include an assembly groove 186. The assembly groove 186 may expose a surface of the third planarization layer 181, corresponding to the area on which the light emitting element ED is disposed. The bank 185 may have some area extending to the third planarization layer 181, while covering the assembly electrodes AE1 and AE2 and the other area exposing some surface areas of the assembly electrode AE1 and AE2. The exposed area of the assembly electrodes AE1 and AE2 may serve to apply an electric field when the color conversion layer is formed based on the dielectrophoresis later.

A color conversion material adhesive layer 187 may be formed on the exposed areas of the assembly electrodes AE1 and AE2 and the third planarization layer 181.

Next, self-assembling of a phosphor constituting the color conversion layer may be performed based on the dielectrophoresis, which will be described referring to FIGS. 5 to 7.

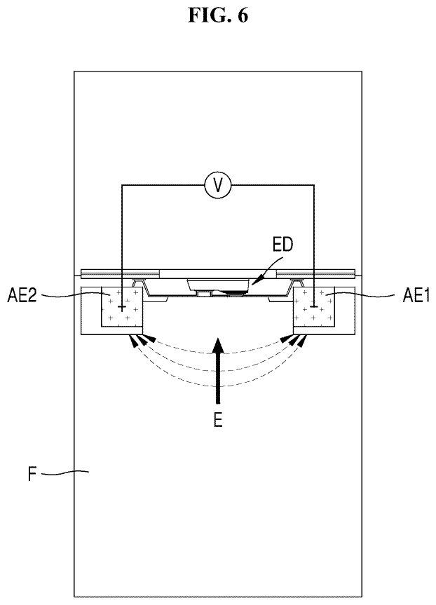

Referring to FIGS. 5 and 6, the substrate 100 on which the light emitting element ED is formed may be introduced into a self-assembly chamber filled with a fluid F in which the plurality of core shell phosphor particles 210 are scattered. For convenience of description, FIG. 5 shows only the light emitting element ED and the pair of assembly electrodes AE1 and AE2 among the components disposed on the substrate 100.

The direction in which the substrate 100 having the light emitting element ED disposed thereon introduced into the self-assembly chamber may be a direction facing each other so that the assembly groove 186 of the light emitting element ED and the fluid F come into contact with each other. The pair of assembly electrodes AE1 and AE2 may be disposed on the substrate 100. The assembly electrodes AE1 and AE2 may generate an electric field when a voltage is applied, to pull the phosphor layer toward the adhesive layer exposed by the assembly groove 186.

The assembly electrodes AE1 and AE2 may be made of a transparent a transparent metal oxide such as indium-tin-oxide (ITO) or indium-zinc-oxide (IZO). The assembly electrodes AE1 and AE2 may include a transparent metal material that may form an electric field.

A magnet M may be disposed on a second surface facing a first surface of the substrate 100 on which the assembly electrodes AE1 and AE2 are disposed. The magnet M may pull the core shell phosphor particles scattered inside the fluid F toward the assembly groove 186.

The phosphor core shell particles 210 may include a phosphor core 200 made of a phosphor and a shell 205 surrounding the outside of the phosphor core 200. The phosphor core 200 may include a phosphor. The phosphor may be a material characterized in emitting light with a long wavelength by short-wavelength energy excitation of a micro LED.

The shell 205 surrounding the outside of the phosphor core 200 may include a nano-coating layer. For example, a material constituting the nano-coating layer may include a metal oxide-based material. For example, the metal oxide-based material may include indium oxide (In₂O₃), silicon oxide (SiO₂), magnesium oxide (MgO), or aluminum oxide (Al₂O₃). The nano-coating layer constituting the shell 205 may coat a surface of the core including the phosphor, thereby preventing moisture penetration and change on a surface of the phosphor. Accordingly, the reliability and performance of the phosphor core shell particles 210 may be improved.

The shell 205 surrounding the outside of the phosphor core 200 may first precede a plasma surface treatment process on the phosphor core 200 to modify the surface of the phosphor core 200, and then perform surface treatment for the phosphor core 200 through a sol-gel process. After that, a stirring and heat treatment process may be performed to discharge the solvent and residue. Accordingly, the phosphor core shell particle 210 may be formed.

The shell 205 surrounding the outside of the phosphor core 200 may include a metal oxide-based material. The metal oxide-based material is polarizable in an electric field. Accordingly, in the aspect of the present disclosure, the color conversion layer may be formed based on the method of self-assembly by applying force in the direction of the electrode using dielectrophoretic force.

Among the metal oxide-based materials, an Indium oxide (In₂O₃) include a magnetic force so that it may move the phosphor core shell particle 210 to a target position by using the magnet.

The magnet M may pull the core shell phosphor particles 210 scattered in the fluid F toward the assembly groove 186.

When an A/C voltage is applied on the assembly electrodes AE1 and AE2, an electric field E may be generated in a direction of the assembly electrodes AE1 and AE2. The shell 205 of the phosphor core shell particles floating around the assembly electrodes AE1 and AE2 may have polarity due to dielectric polarization. The dielectric polarized phosphor core shell particles 210 may move in a specific direction or be fixed at a specific position by the electric field generated around the assembly electrodes AE1 and AE2, which is called dielectrophoresis DEP.

The dielectrophoresis may be understood as a phenomenon in which a directional force is applied to a particle by a dipole induced in the particle when the particle is disposed in a non-uniform electric field. The strength of dielectrophoretic force varies depending on the electrical characteristics of particles and medium, and the motion of the particles may be controlled based on this. The dielectrophoresis differs from electrophoresis in that it is possible to control the motion of uncharged particles.

The strength of the dielectrophoresis may be proportional to that of the electric field. Controlling the movement of the phosphor core shell particles may vary depending on the degree of dielectric polarization in the shell 205. When the polarity of the particle is greater than the polarity of the medium, the particle may move in a direction in which the electric field is formed relatively densely. Accordingly, the movement of the particle may be controlled by forming the electric field density non-uniform in the area on which the assembly electrodes AE1 and AE2 are disposed.

As described above, while generating the electric field in the area where the assembly electrodes AE1 and AE2 are disposed, the movement of the particles may be controlled toward the assembly electrodes AE1 and AE2 so that the plurality of phosphor core shell particles 210 may be aligned and fixed on the color conversion material adhesive layer 187, thereby forming the color conversion layer 190.

The color conversion layer 190 formed by the dielectrophoresis may have a high phosphor density and the increased probability that blue light emitted from the light emitting element ED is absorbed and converted after being incident on the phosphor, thereby improving color conversion efficiency. In addition, since the color conversion layer 190 uses the dielectrophoresis, the thickness of the color conversion layer 190 formed in the assembly groove 186 may be uniform regardless of location. Accordingly, front luminance may increase and the reliability and color gamut of the device may be improved.

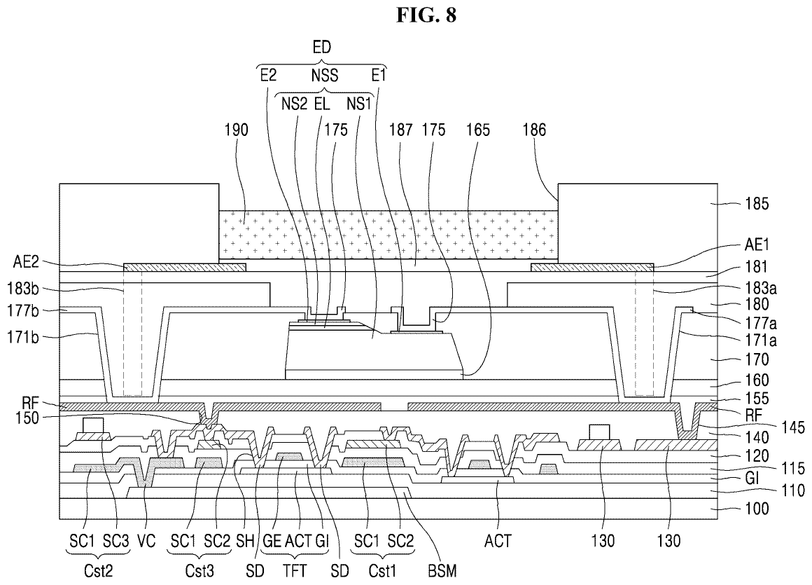

Referring to FIG. 8, the color conversion layer 190 may be fixed through the color conversion material adhesive layer 187. Hence, the cover layer 195 may be disposed on the bank 185 including the color conversion layer 190, to constitute the display apparatus shown in FIG. 2. The cover layer 195 may further include a functional optical film such as an anti-scattering film. The cover layer 195 may be attached on the color conversion layer 190 via an optical clear adhesive OCA but the aspect is not limited thereto.

According to the aspects of the present disclosure, the high density phosphor color conversion layer may be formed so that color gamut and color conversion efficiency may be improved thereby improving productivity.

In addition, since the color conversion layer may be formed by using the dielectrophoresis, contact time may be reduced in comparison with the conventional deposition of the phosphor by using the inkjet method, thereby improving productivity.

In addition, the phosphor layer may be easily fixed to the position at which the color conversion layer has to be disposed by applying the material having adhesiveness to the position at which the color conversion layer will be formed, thereby realizing process optimization.

Although the present disclosure has been described with reference to the exemplified drawings, it is to be understood that the present disclosure is not limited to the aspects and drawings disclosed in this specification, and those skilled in the art will appreciate that various modifications are possible without departing from the scope and spirit of the present disclosure. Further, although the operating effects according to the configuration of the present disclosure are not explicitly described while describing an aspect of the present disclosure, it should be appreciated that predictable effects are also to be recognized by the configuration.

It will be apparent to those skilled in the art that various modifications and variations can be made in the display apparatus and the method for manufacturing the same of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display apparatus comprising:
a light emitting element disposed on a substrate:
a planarization layer covering the light emitting element and having a plurality of holes disposed on both sides of the light emitting element interposed therebetween;
a plurality of wire electrodes disposed on exposed surfaces of the plurality of holes and electrically connected with the light emitting element;
a plurality of assembly electrodes disposed on the planarization layer;
a bank disposed on the plurality of assembly electrodes and comprising an assembly groove; and
a color conversion layer disposed inside the assembly groove.

2. The display apparatus of claim 1, wherein the light emitting element comprises a micro LED emitting a blue light, and
the color conversion layer emits a different color light from the blue light while the blue light passing therethrough.

3. The display apparatus of claim 1, wherein the assembly electrodes are disposed on both sides of the light emitting element interposed therebetween, spaced apart from each other.

4. The display apparatus of claim 1, wherein each of the plurality of assembly electrodes protrudes from an edge of the bank toward the assembly groove and overlaps the color conversion layer.

5. The display apparatus of claim 1, wherein the assembly electrode comprises a transparent electrode comprising a metal oxide including indium-tin-oxide (ITO) or indium-zinc-oxide (IZO).

6. The display apparatus of claim 1, further comprising a buried pattern filling in the plurality of holes and disposed on the plurality of wire electrodes, wherein the plurality of assembly electrodes are disposed above the buried pattern;
a through-electrode penetrating the buried pattern,
wherein one surface of the through-electrode contacts a rear surface of the assembly electrode and another surface thereof is connected with each of the plurality of wire electrodes electrically connected with the light emitting element.

7. The display apparatus of claim 1, wherein the color conversion layer has a uniform thickness at a center or edge of the assembly groove.

8. The display apparatus of claim 1, wherein the color conversion layer comprises a plurality of phosphor core shell particles comprising a phosphor core, and a shell surrounding an outside surface of the phosphor core.

9. The display apparatus of claim 8, wherein the shell comprises a material that is polarizable in an electric field.

10. The display apparatus of claim 9, wherein the polarizable material is a nano-coating layer comprising a metal oxide-based material.

11. The display apparatus of claim 10, wherein the metal oxide-based material comprises indium oxide, silicon oxide, magnesium oxide or aluminum oxide.

12. A method for manufacturing a display apparatus comprising:
preparing a substrate;
wherein the substrate comprises;
a light emitting element; a planarization layer covering the light emitting element and comprising a plurality of holes disposed on both sides with the light emitting element interposed therebetween; a plurality of wire electrodes disposed on an exposed surfaces of the plurality of holes and electrically connected with the light emitting element; a plurality of assembly electrodes disposed on the planarization layer; a bank disposed on the plurality of assembly electrodes and comprising an assembly groove; and a color conversion material adhesive layer disposed inside the assembly groove;
disposing the substrate in a fluid in which core shell phosphor particles are scattered;
moving the core shell phosphor particles toward the assembly groove;
generating an electric field around the plurality of assembly electrodes; and
forming a color conversion layer by moving the core-shell phosphor particles dielectrically polarized by the electric field toward the assembly electrode and fixing the dielectrically polarized core shell phosphor particles on the color conversion material adhesive layer.

13. The method for manufacturing the display apparatus of claim 12, wherein the electric field is generated by applying an alternating voltage on the assembly electrode.

14. The method for manufacturing the display apparatus of claim 12, wherein the phosphor core shell particle comprises a phosphor core, and a shell surrounding the phosphor core, and the shell comprises a material that is polarizable in an electric field.

15. The method for manufacturing the display apparatus of claim 14, wherein the polarizable material comprises a metal oxide-based material of indium oxide, silicon oxide, magnesium oxide or aluminum oxide.
